(19) United States
(12) Patent Application Publication
(10) Pub. No.: US 2013/0256908 A1
(43) Pub. Date: Oct. 3, 2013

(54) INTER-DIE CONNECTION WITHIN AN INTEGRATED CIRCUIT FORMED OF A STACK OF CIRCUIT DIES

(71) Applicant: Teresa Louise Mclaurin, Austin, TX (US)

(72) Inventor: Teresa Louise Mclaurin, Austin, TX (US)

(73) Assignee: ARM LIMITED, Cambridge (GB)

(21) Appl. No.: 13/992,399

(22) PCT Filed: Dec. 13, 2010
(86) PCT No.: PCT/US2010/059996

§ 371 Date: Jun. 7, 2013

(51) Int. Cl. H01L 25/065; H01L 21/50

(52) U.S. Cl. CPC H01L 25/0657; H01L 21/50
USPC 257/774; 438/109

(57) ABSTRACT

An integrated circuit is formed of a plurality of circuit dies 22, 24 having through silicon vias (TSVs) passing there-through. The placement patterns of the through silicon vias differ between the circuit dies. An inter-die routing layer is provided either in a face of a substrate of one of the circuit dies or in an outer face of a layer of processing circuitry of one of the circuit dies. The inter-die routing layer bridges the gaps between the vias and the connection points of different circuit dies. The inter-die routing layer may be formed of metal tracks.

### BACKGROUND OF THE INVENTION

1. Field of the Invention

This invention relates to the field of integrated circuits. More particularly, this invention relates to integrated circuits formed as a stack of circuit dies.

2. Description of the Prior Art

It is known to provide integrated circuits formed as a stack of circuit dies. Electrical connections can he made between the circuit dies of the stack in a variety of different ways. One known way of electrically connecting the circuit dies is to use through silicon vias (TSVs). Such TSVs permit electrical connections to be made between adjacent circuit dies as well as permitting electrical connections to be made between non-adjacent circuit dies using TSVs passing through one or more intervening circuit dies.

It will be appreciated that the TSVs in adjacent circuit dies need to be accurately aligned such that a conductive path is formed when the circuit dies are joint together to form the stack. It is normal for the circuit dies to be specifically designed to operate in conjunction with each other such that the TSVs in each circuit die are aligned and laid out in the same pattern. When the circuit dies are designed to work together in this way, the TSVs can be placed such that the requirements of alignment are directly met.

It has also been proposed in the publication “What, Why and How of Through-Silicon Vias” of Mentor Graphics Corporation published on 10 Jun. 2009 to provide a TSV “interposer” between two circuit dies that were not originally designed to work together. The TSV interposer serves as a passive TSV chip that provides for via layout re-mapping from one circuit die to another circuit die. This permits combinations of circuit dies that would otherwise be incompatible to be made.

There are a number of problems with the TSV interposer approach. The TSV interposer adds an additional layer within the stack increasing the manufacturing cost and manufacturing complexity. Furthermore, the signal path through the TSV interposer may not be as quick as a more direct path.

### SUMMARY OF THE INVENTION

Viewed from one aspect the present invention provides an integrated circuit comprising:

a plurality of circuit dies stacked together, each of said plurality of circuit dies having a substrate layer with a layer of processing circuitry formed thereupon; wherein

at least one of said plurality of circuit dies has a plurality of vias extending to a face of said at least one of said plurality of dies;

at least one of said plurality of circuit dies has an inter-die routing layer providing a plurality of conduction paths, at least one of said plurality of conduction paths extending between a via position at which one of said vias extends to said face and a connection position at which a conductive connection is made to an adjacent circuit die of said plurality of circuit dies; and

said vias in said at least one of said plurality of circuit dies have a via placement pattern, said connection positions in said adjacent circuit die have a connection position placement pattern, said via placement pattern is different from said connection position placement pattern and said inter-die routing layer provides said conduction paths to bridge gaps between via positions and connection positions.

The present technique recognises that although circuit dies to be stacked together may be incompatible for directly joining together it is possible to add an inter-die routing layer to at least one of the circuit dies to provide a conduction path between a via in one circuit die and a connection position within an adjacent circuit die. The inter-die routing layer is provided within one of the circuit dies which itself has a substrate layer and a layer of processing circuitry thereby avoiding the need to use a TSV interposer. The technique recognises that while adjacent circuit dies may have vias and connection positions set out with different and incompatible placement patterns, it is possible to add an inter-die routing layer with little disruption to the design and performance of the associated circuit die.

One possibility is that the inter-die routing layer is formed on an outer face of the substrate layer when the vias extend through the substrate layer to this outer face. This leaves the layer of processing circuitry on the other face of the substrate undisturbed.

Another possibility is to provide the inter-die routing layer on an outer face of the layer of processing circuitry. The layer of processing circuitry will typically include many metal layers providing intra-die electrical connections and the inter-die routing layer can be added as an outermost layer with little disruption to the underlying layer of processing circuitry.

It will be appreciated that the vias to which electrical connection is to be made can have a wide variety of different forms. These vias may extend through the substrate layer, the layer of processing circuitry or both the substrate layer and the layer of processing circuitry in the case of through silicon vias. Vias extending through both the substrate layer and the layer of processing circuitry are suitable for permitting signals to be passed through a circuit die to another circuit die whereas vias through only the substrate or through only the layer of processing circuitry are suitable for use at either end of a stack of circuit dies or within a stack comprising only two circuit dies.

The connection position within the adjacent circuit die may or may not be directly to a via in the adjacent circuit die. In one form the connection position may be a via position in the adjacent circuit die. In another form the connection position may be part of an intra-die metal layer in the adjacent circuit die (which may or may not connect to a via in the adjacent circuit die).

The inter-die routing layer may also have a three-dimensional form extending laterally when passing through the substrate layer.

The inter-die routing layer may be formed of a variety of different materials. The material of the inter-die routing layer should be conductive. In sonic embodiments the inter-die routing layer is a metal layer, such as copper or tungsten.

The gaps between the via positions and the connection positions may be greater than the manufacturing tolerance in locating the connection position relative to the via position and accordingly require the inter-die routing via the inter-die routing layer.

The substrate may be a silicon substrate.

Viewed from another aspect the present invention provides an integrated circuit comprising:

a plurality of circuit dies stacked together, each of said plurality of circuit dies having a substrate layer with a layer of processing circuitry formed thereupon; wherein

at least one of said plurality of circuit dies has a plurality of vias extending to a face of said at least one of said plurality of dies;

at least one of said plurality of circuit dies has an inter-die routing layer providing a plurality of conduction paths, at least one of said plurality of conduction paths extending between a via position at which one of said vias extends to said face and a connection position at which a conductive connection is made to an adjacent circuit die of said plurality of circuit dies; and

said connection position is displaced from said via position by a distance greater than a manufacturing tolerance in locating said connection position relative to said via position.

Viewed from a further aspect the present invention provides an integrated circuit comprising:

a plurality of circuit dies stacked together, each of said plurality of circuit dies having a substrate layer with a layer of processing circuitry formed thereupon; wherein

at least one of said plurality of circuit dies has a plurality of vias extending to a face of said at least one of said plurality of dies;

at least one of said plurality of circuit dies has an inter-die routing layer.

Viewed from a further aspect the present invention provides a method of connecting adjacent circuit dies in a stack of circuit dies each having a substrate layer with a layer of processing circuitry formed thereupon, said method comprising the steps of:

forming vias extending through to a face of a first circuit die; and

forming an inter-die routing layer to provide a plurality of conduction paths, at least one of said plurality of conduction paths extending between a via formed in said first circuit die and a connection position within a second circuit die adjacent said first circuit die within said stack; wherein

said vias in said first circuit die have a via placement pattern, said connection positions in said second circuit die have a connection position placement pattern, said via placement pattern is different from said connection position placement pattern, and said inter-die routing layer provides said conduction paths to bridge gaps between through via positions and connection positions.

Viewed from a further aspect the present invention provides a method of connecting adjacent circuit dies in a stack of circuit dies each having a substrate layer with a layer of processing circuitry formed thereupon, said method comprising the steps of:

forming vias extending through to a face of a first circuit die; and

forming an inter-die routing layer to provide a plurality of conduction paths, at least one of said plurality of conduction paths extending between a via formed in said first circuit die and a connection position within a second circuit die adjacent said first circuit die within said stack; wherein

said connection position is displaced from via position by a distance greater than a manufacturing tolerance in locating said connection position relative to said via position.

Viewed from a further aspect the present invention provides a method of connecting adjacent circuit dies in a stack of circuit dies each having a substrate layer with a layer of processing circuitry formed thereupon, said method comprising the steps of:

forming vias extending through to a face of a first circuit die; and

forming an inter-die routing layer to provide a plurality of conduction paths, at least one of said plurality of conduction paths extending between a via formed in said first circuit die and a connection position within a second circuit die adjacent said first circuit die within said stack.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates a stack of circuit dies with through silicon vias in accordance with the prior art;

FIG. 2 schematically illustrates two circuit dies with different placement patterns of through silicon vias and a corresponding inter-die routing layer;

FIG. 3 schematically illustrates another example embodiment of a stack of circuit dies and an inter-die routing layer;

FIG. 4 schematically illustrates an example embodiment of a hardened CPU macrocell forming one circuit die for use within a stack of circuit dies in connection with an inter-die routing layer;

FIG. 5 schematically illustrates an example embodiment in which the inter-die routing layer is formed on an outer face of a substrate layer;

FIG. 6 is a further example embodiment in which the inter-die routing layer is formed on an outer face of a layer of processing circuitry;

FIG. 7 schematically illustrates an example embodiment having three circuit dies in a stack;

FIG. 8 schematically illustrates an example embodiment in which the inter-die routing layer is formed within a substrate layer;

FIG. 9 is a flow diagram schematically illustrating a design process for adding an inter-die routing layer to a circuit die.

### DESCRIPTION OF THE EMBODIMENTS

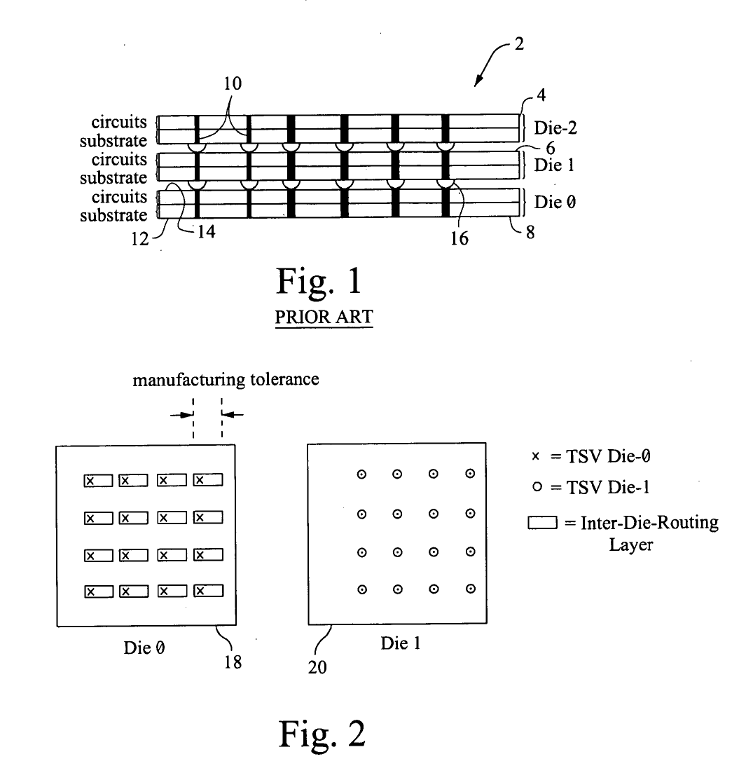

FIG. 1 illustrates a prior art integrated circuit 2 formed of a stack of circuit dies 4, 6, 8 including an array of TSVs 10 having the same placement pattern within each circuit die 4, 6, 8. Each of the circuit dies includes a substrate layer 12 and a layer of processing circuitry 14. The circuit dies 4, 6, 8 are joined together in a stack to provide electrical conduction paths between the circuit dies 4, 6, 8. Small solder balls 16 are provided over the ends of the TSVs 10 on one face of the circuit dyes 4, 6, 8 to facilitate good electrical connection with the adjacent circuit die.

FIG. 2 illustrates two circuit dies 18, 20 which are to form an integrated circuit by being stacked on top of each other. As will be seen, the TSVs in the different circuit dies 18, 20 have different placement patterns. When the two dies 18, 20 are placed in a stack so as to be abutting each other, the TSVs of the circuit die 20 are all displaced laterally by the same amount from the TSVs within the circuit die 18 to which they are to be connected. This displacement is greater than the manufacturing tolerance in locating the connection position relative to the via position and is a systematic displacement associate with the different designs of the two circuit dies 18, 20. The circuit die 18 is provided with an inter-die routing layer in its substrate surface to provide conduction paths to the corresponding through silicon vias within the circuit die 20 when the circuit dies 18, 20 are placed on top of each other.

The inter-die routing layer may be formed by etching the pattern of the inter-die routing layer into the substrate of the circuit die 18 in which the TSVs are located and then filling the etched locations with a metal layer, such as copper or tungsten. It will be appreciated by those in this technical field that there are many different ways in which the inter-die routing layer may be formed and the present techniques encompass these variations.

The example illustrated in FIG. 2 shows the circuit die 18 as including an inter-die routing layer and the circuit die 20 as including only the TSVs. It will be appreciated that in other embodiments both of the circuit dies 18, 20 could include inter-die routing layers with these being arranged to contact each other.

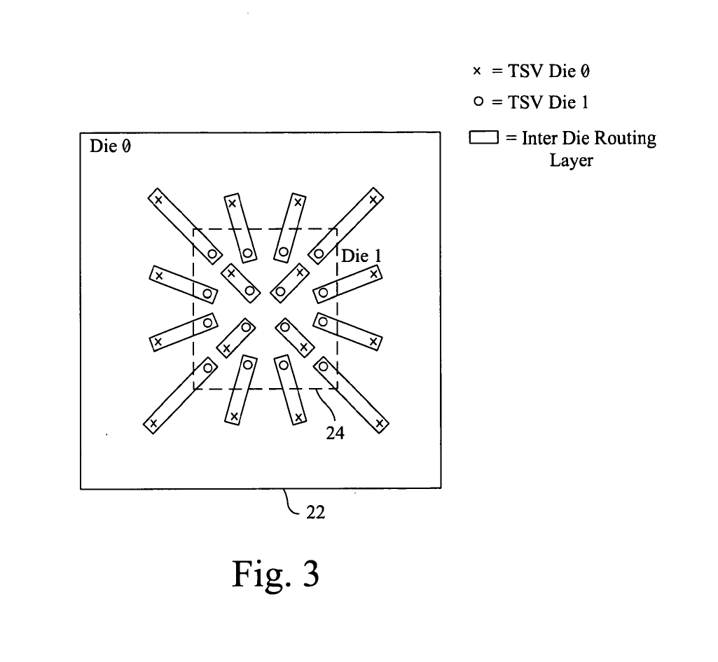

FIG. 3 is an example embodiment showing how two circuit dies 22, 24 may be placed together with an inter-die routing layer formed within the circuit die 22. In this example the placement pattern of the TSVs in the different dies varies due to the pitch between the TSVs differing between the two circuit dies 22, 24. As a consequence the inter-die routing layer has a more complex form. The inter-die routing layer may be formed in the substrate of the circuit die 22 with the circuit die 24 then being placed adjacent the substrate of the circuit die 22. In another variant the inter-die routing layer may be formed in the face of the layer of processing circuits on the circuit die 22 with the circuit die 24 then being placed on top of this layer of processing circuits.

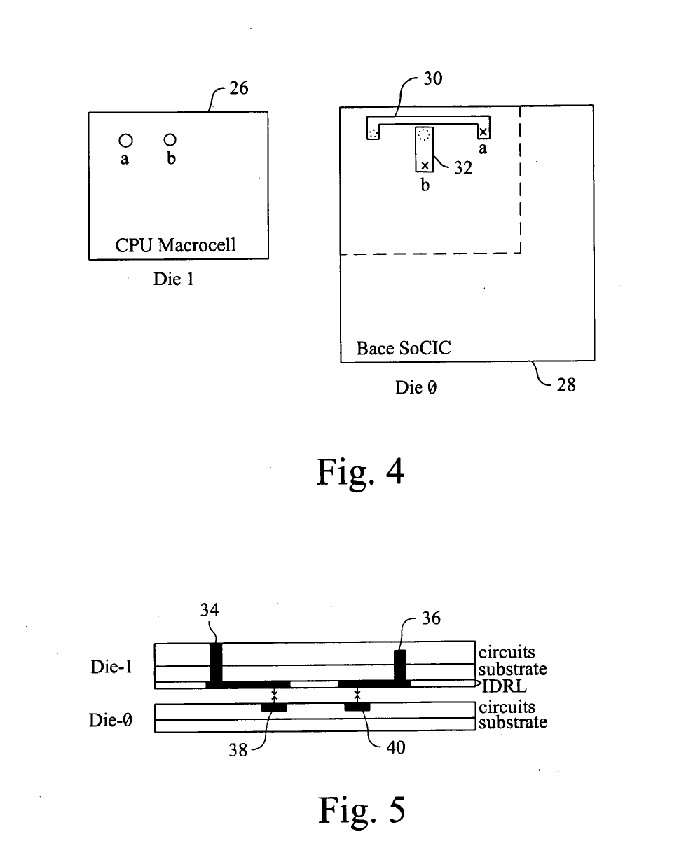

FIG. 4 illustrates a further example embodiment. In this embodiment a circuit die 26 in the form of a hardened CPU macrocell is formed with. TSVs schematically illustrated as a and b. The circuit die 26 has a different size from that of circuit die 28 and is in the form of a base system-on-chip integrated circuit die. The corresponding TSVs a and b on the circuit die 28 are disposed at significantly different positions.

When the circuit die 26 is placed over the circuit die 28 in the upper left hand corner thereof, an inter-die routing layer in the form of metal tracks 30, 32 is provided either on the circuit die 26 or on the circuit die 28. As will be seen, these metal tracks 30, 32 have a shape such that they can be routed to avoid one another. It will be appreciated by those in this technical field that signal routing algorithms of the type used in integrated circuit design may be used to devise the routing and placement of the metal tracks 30, 32 required to provide conduction paths between vias within the circuit die 26 and connection points within the circuit die 28. In practice typically many tens or hundreds of conduction paths may be provided between the circuit dies 26, 28 in order to facilitate the signals which need to be passed therebetween.

FIG. 5 illustrates an example embodiment in which a TSV 34 and a via 36 within Die1 are provided with conduction paths using the inter-die routing layer formed on the face of the substrate layer of die 1. These conductive paths electrically connect to respective connection points 38, 40 provided on the face of the layer of processing circuits within Die0.

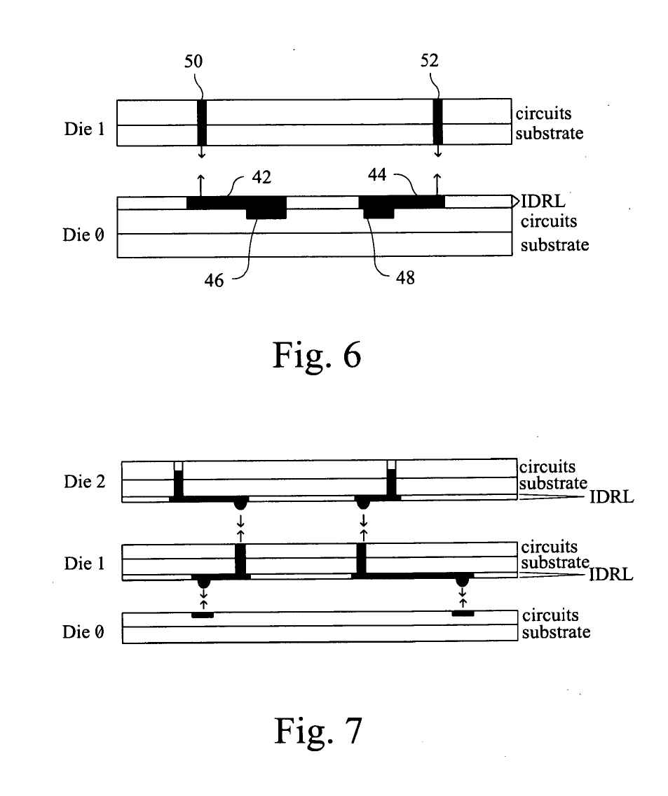

FIG. 6 illustrates a further example embodiment. In this example embodiment the inter-die routing layer is formed of metal tracks 42, 44 formed in an upper face of the layer of processing circuits of Die0. These metal tracks 42, 44 bridge the gap due to the different placement patterns between the connection positions 46, 48 of Die 0 and corresponding TSVs 50, 52 in Die1.

FIG. 7 schematically illustrates a further example embodiment. In this example embodiment Die0 has connection points formed on a face of the layer of processing circuits. Die1 has TSVs providing an electrical path through Die1 to Die2. Die2 has vias which pass through the substrate and partway into the layer of processing circuitry to make contact with metal layers or other parts of the layer of processing circuitry as required. Inter-die routing layers are formed in the face of the substrate of both Die1 and Die2. The metal tracks forming these inter-die routing layers are provided with solder balls at the points at which they are to contact the adjacent circuit die to facilitate good electrical contact therebetween,

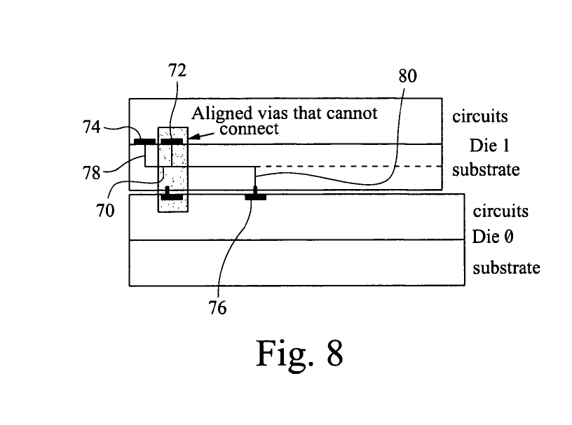

FIG. 8 schematically illustrates an example embodiment in which two vias 70, 72 from adjacent dies (Die 0 and Die 1) are aligned and would connect if via 72 extended through the substrate. These vias 70, 72 are not intended to connect, but should connect to other vias 74, 76. The inter-die routine 78, 80 in this case has a three-dimensional form within the substrate permitting the desired electrical connections to be made.

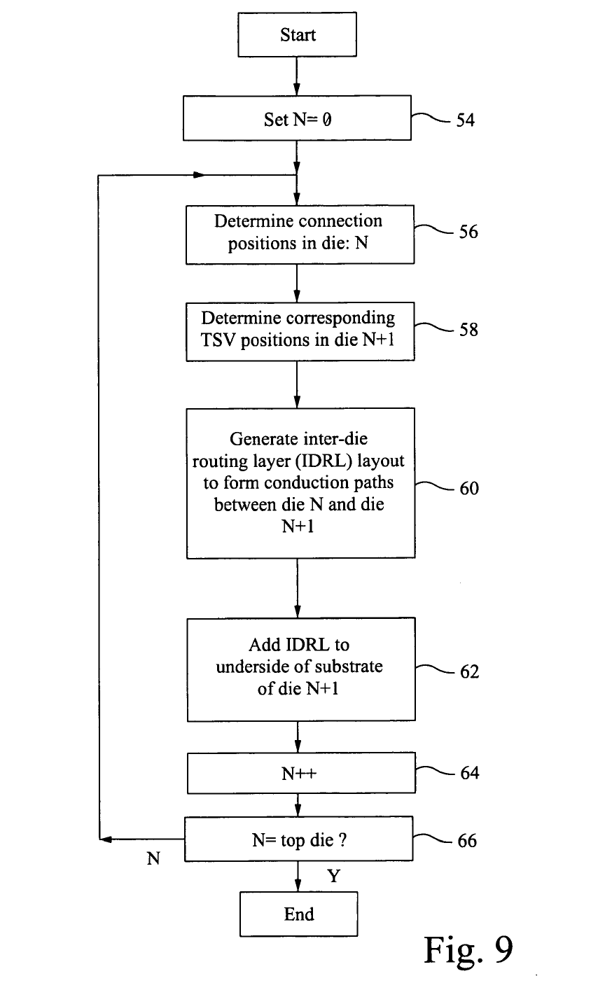

FIG. 9 is a flow diagram schematically illustrating the design process by which inter-die routing layers may be added to circuit dies within a stack forming an integrated circuit. At step 54 a variable N is initially set to a value 0 corresponding to the first circuit die within a stack of circuit dies. Step 56 determines the connection positions within DieN. Step 58 then determines the TSV positions within DieN+1 to which it is desired to electrically connect respective connection positions within DieN. Step 60 generates the inter-die routing layer layout to conform conduction paths between DieN and DieN+1 in order to provide the desired electrical connections. It will be appreciated that routing and placement algorithms may be used to determine the size and routing of the individual conduction paths to be formed which together serve as the inter-die routing layer to be added.

Step 62 then adds the inter-die routing layer to the outer face of the substrate layer of DieN+1. It will be appreciated that in other embodiments the inter-die routing layer could be added to the outer surface of the layer of processing circuitry of DieN.

Step 64 increments the value of N. Step 66 determines whether N has now reached a value corresponding to the last die within the stack of circuit dies. If the last die has been reached then the processing terminates. If the last die has not been reached then processing returns to step 56. It will be appreciated that the connection positions in DieN determined at step 56 may be the position of vias within DieN, connection positions formed in an outermost metal layer of a layer of processing circuitry or through dies passing completely from one face of a circuit die to another face of a circuit die. An individual circuit die may also include a mixture of such forms of the connection positions.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

We claim:

1. An integrated circuit comprising:
a plurality of circuit dies stacked together, each of said plurality of circuit dies having a substrate layer with a layer of processing circuitry formed thereupon; wherein
at least one of said plurality of circuit dies has a plurality of vias extending to a face of said at least one of said plurality of dies;
at least one of said plurality of circuit dies has an inter-die routing layer providing a plurality of conduction paths, at least one of said plurality of conduction paths extending between a via position at which one of said vias extends to said face and a connection position at which a conductive connection is made to an adjacent circuit die of said plurality of circuit dies; and
said vias in said at least one of said plurality of circuit dies have a via placement pattern, said connection positions in said adjacent circuit die have a connection position placement pattern, said via placement pattern is different from said connection position placement pattern and said inter-die routing layer provides said conduction paths to bridge gaps between via positions and connection positions.

2. An integrated circuit as claimed in claim 2, wherein said plurality of vias extend through one of: (i) said substrate layer; (ii) said layer of processing circuitry; and (iii) said substrate layer and said layer of processing circuitry.

3. An integrated circuit as claimed in claim 1, wherein said connection position is one of: (i) a via position of a via in said adjacent circuit die; and (ii) a position within an intra-die metal layer in said adjacent circuit die.

4. An integrated circuit as claimed 2, wherein said plurality of vias extend through said substrate layer and said inter-die routing layer is formed in an outer face of said substrate layer.

5. An integrated circuit as claimed in claim 1, wherein at least one of said plurality of vias does not extend through said substrate layer and said inter-die routing layer is provided within said substrate layer to provide a conduction path from said via to a point on a face of said at least one of said plurality of circuit dies that is displaced from said via in a plane of said circuit die.

6. An integrated circuit as claimed 1, wherein said adjacent circuit die comprises a substrate layer having a layer of processing circuitry formed thereupon and said inter-die routing layer is formed in an outer face of said layer of processing circuitry.

7. An integrated circuit as claimed in claim 1, wherein inter-die routing layer is a metal layer.

8. An integrated circuit as claimed in claim 1, wherein said connection position is displaced from said via position by a distance greater than a manufacturing tolerance in locating said connection position relative to said via position.

9. An integrated circuit as claimed in claim 1, wherein said at least one of said plurality of circuit dies having said inter-die routing layer includes a macrocell with a fixed circuit layout including a fixed layout of vias and said inter-die routing layer serves to adapt said fixed layout of vias to a different layout of connection positions in said adjacent circuit die.

10. An integrated circuit as claimed in claim 1, wherein said substrate is a silicon substrate.

11. An integrated circuit comprising:
a plurality of circuit dies stacked together, each of said plurality of circuit dies having a substrate layer with a layer of processing circuitry formed thereupon; wherein
at least one of said plurality of circuit dies has a plurality of vias extending to a face of said at least one of said plurality of dies;
at least one of said plurality of circuit dies has an inter-die routing layer providing a plurality of conduction paths, at least one of said plurality of conduction paths extending between a via position at which one of said vias extends to said face and a connection position at which a conductive connection is made to an adjacent circuit die of said plurality of circuit dies; and
said connection position is displaced from said via position by a distance greater than a manufacturing tolerance in locating said connection position relative to said via position.

12. An integrated circuit comprising:
a plurality of circuit dies stacked together, each of said plurality of circuit dies having a substrate layer with a layer of processing circuitry formed thereupon; wherein
at least one of said plurality of circuit dies has a plurality of vias extending to a face of said at least one of said plurality of dies;
at least one of said plurality of circuit dies has an inter-die routing layer.

13. A method of connecting adjacent circuit dies in a stack of circuit dies each having a substrate layer with a layer of processing circuitry formed thereupon, said method comprising the steps of:
forming vias extending through to a face of a first circuit die; and
forming an inter-die routing layer to provide a plurality of conduction paths, at least one of said plurality of conduction paths extending between a via formed in said first circuit die and a connection position within a second circuit die adjacent said first circuit die within said stack; wherein
said vias in said first circuit die have a via placement pattern, said connection positions in said second circuit die have a connection position placement pattern, said via placement pattern is different from said connection position placement pattern, and said inter-die routing layer provides said conduction paths to bridge gaps between through via positions and connection positions.

14. A method of connecting adjacent circuit dies in a stack of circuit dies each having a substrate layer with a layer of processing circuitry formed thereupon, said method comprising the steps of:
forming vias extending through to a face of a first circuit die; and
forming an inter-die routing layer to provide a plurality of conduction paths, at least one of said plurality of conduction paths extending between a via formed in said first circuit die and a connection position within a second circuit die adjacent said first circuit die within said stack; wherein
said connection position is displaced from via position by a distance greater than a manufacturing tolerance in locating said connection position relative to said via position.

15. A method of connecting adjacent circuit dies in a stack of circuit dies each having a substrate layer with a layer of processing circuitry formed thereupon, said method comprising the steps of:
forming vias extending through to a face of a first circuit die; and
forming an inter-die routing layer to provide a plurality of conduction paths, at least one of said plurality of conduction paths extending between a via formed in said first circuit die and a connection position within a second circuit die adjacent said first circuit die within said stack.
